(19) United States
(12) Patent Application Publication
(10) Pub. No.: US 2008/0029883 A1
(43) Pub. Date: Feb. 7, 2008

(54) Diamond composite heat spreaders having low thermal mismatch stress and associated methods

(76) Inventor: Chien-Min Sung, Taipei County (TW)

Correspondence Address: THORPE NORTH & WESTERN, LLP., 8180 SOUTH 700 EAST, SUITE 350, SANDY, UT, 84070, US

(21) Appl. No.: 11/893,602

(22) Filed: Aug. 14, 2007

Related U.S. Application Data
(62) Division of application No. 11/266,015, filed on Nov. 2, 2005.
(63) Continuation-in-part of application No. 11/056,339, filed on Feb. 10, 2005.
Application No. 11/056,339 is a continuation-in-part of application No. 10/775,543, filed on Feb. 9, 2004, now Pat. No. 6,987,318.
Application No. 10/775,543 is a continuation-in-part of application No. 10/453,469, filed on Jun. 2, 2003, now Pat. No. 6,984,888.
Application No. 10/775,543 is a continuation-in-part of application No. 10/270,018, filed on Oct. 11, 2002, now Pat. No. 7,173,334.
(60) Provisional application No. 60/681,677, filed on May 16, 2005.

(51) Int. Cl. H01L 23/373

(52) U.S. Cl. 257/720; 257/E23.111

(57) ABSTRACT

A diamond composite heat spreader having a low thermal mismatch stress can improve reliability and cost of diamond-based heat spreaders. A diamond composite heat spreader can have a diamond film and a thermally conductive base having a residual thermal mismatch stress which is less than about 75% of a residual thermal mismatch stress which would result from forming the diamond film on the thermally conductive base using a high temperature deposition process at 700° C. The diamond film can be formed on the thermally conductive base using a low temperature vapor deposition process.

### RELATED APPLICATIONS

This application is a divisional application of U.S. patent application Ser. No. 11/266,015, filed Nov. 2, 2005 which claims the benefit of U.S. Provisional Application No. 60/681,677, filed May 16, 2005, and which is also a continuation-in-part of U.S. Pat. No. 6,987,318, which are each incorporated by reference herein.

### FIELD OF THE INVENTION

The present invention relates to diamond composite devices and systems that can be used to conduct or absorb heat away from a heat source. Accordingly, the present invention involves the fields of chemistry, physics, semiconductor technology, and materials science.

### BACKGROUND OF THE INVENTION

Progress in the semiconductor industry has been following the trend of Moore's Law that was proposed in 1965 by then Intel's cofounder Gordon Moore. This trend requires that the capability of integrated circuits (IC) or, in general, semiconductor chips double every 18 months. Thus, the number of transistors on a central processing unit (CPU) in 2002 may approach 100 million. As a result of this densification of circuitry, line-width in 2003 narrowed to 0.13 micrometer and more advanced chips are using wires as thin as 0.09 micrometer (90 nm).

Along with such advances comes various design challenges. One of the often overlooked challenges is that of heat dissipation. Most often, this phase of design is neglected or added as a last minute design before the components are produced. According to the second law of thermodynamics, the more work that is performed in a closed system, the higher entropy it will attain. With the increasing power of a CPU, the larger flow of electrons produces a greater amount of heat. Therefore, in order to prevent the circuitry from shorting or burning out, the heat resulting from the increase in entropy must be removed. Many CPUs have a power of about 60 watts (W). Further, a CPU made with 0.13 micrometer technology can exceed 100 watts. Current methods of heat dissipation, such as by using metal (e.g., Al or Cu) fin radiators, and water evaporation heat pipes, will be inadequate to sufficiently cool future generations of CPUs. As evidenced by Intel's recent announcement that the CPU's will be split to form multiple processing centers and provide increased computational speed without real significant increases in clock speed. This dramatic change in processing design and architecture is largely the result of an inability to adequately cool CPUs operating at high speeds. In addition, current technologies are generally not limited by the ability to increase computational speed per se; rather, the difficulty largely lies in the ability to remove heat at a sufficient rate to prevent these chips from burning out. Thus, most CPUs also include governors which limit the clock speed below what the chip is actually capable of reaching.

Ceramic heat spreaders (e.g., AlN) and metal matrix composite heat spreaders (e.g., SiC/Al) have been used to cope with the increasing amounts of heat generation. However, such materials have a thermal conductivity that is no greater than that of Cu, hence, their ability to dissipate heat from semiconductor chips is limited.

A typical semiconductor chip contains closely packed metal conductors (e.g., Al, Cu) and ceramic insulators (e.g., oxide, nitride). The thermal expansion of metal is typically 5-10 times that of ceramics. When the chip is heated to above 60° C., the mismatch of thermal expansions between metal and ceramics can create microcracks. The repeated cycling of temperature tends to aggravate the damage to the chip. As a result, the performance of the semiconductor will deteriorate. Moreover, when temperatures reach more than 90° C., the semiconductor portion of the chip may become a conductor so the function of the chip is lost. In addition, the circuitry may be damaged and the semiconductor is no longer usable (i.e. becomes “burned out”). Thus, in order to maintain the performance of the semiconductor, its temperature must be kept below a threshold level (e.g., 90° C.).

A conventional method of heat dissipation is to contact the semiconductor with a metal heat sink. A typical heat sink is made of aluminum that contains radiating fins. These fins are attached to a fan. Heat from the chip will flow to the aluminum base and will be transmitted to the radiating fins and carried away by the circulated air via convection. Heat sinks are therefore often designed to have a high heat capacity to act as a reservoir to remove heat from the heat source.

Alternatively, a heat pipe may be connected between the heat sink and a radiator that is located in a separated location. The heat pipe contains water vapor that is sealed in a vacuum tube. The moisture will be vaporized at the heat sink and condensed at the radiator. The condensed water will flow back to the heat sink by the wick action of a porous medium (e.g., copper powder). Hence, the heat of a semiconductor chip is carried away by evaporating water and removed at the radiator by condensing water.

Although heat pipes and heat plates may remove heat very efficiently, the complex vacuum chambers and sophisticated capillary systems prevent designs small enough to dissipate heat directly from a semiconductor component. As a result, these methods are generally limited to transferring heat from a larger heat source, e.g., a heat sink. Thus, removing heat via conduction from an electronic component is a continuing area of research in the industry.

One promising alternative that has been explored for use in heat spreaders is diamond-containing materials. Diamond can carry away heat much faster than any other material. The thermal conductivity of diamond at room temperature (about 2000 W/mK) is five times higher than copper (about 400 W/mK) and eight times that of aluminum (250 W/mK), the two fastest metal heat conductors commonly used. Moreover, the thermal diffusivity of diamond (12.7 cm²/sec) is eleven times that of copper (1.17 cm²/sec) or aluminum (0.971 cm²/sec). The ability for diamond to carry away heat without storing it makes diamond an ideal heat spreader. In contrast to heat sinks, a heat spreader acts to quickly conduct heat away from the heat source without storing it. Table 1 shows various thermal properties of several materials as compared to diamond (values provided at 300 K).

TABLE 1

| | Thermal | | Thermal |
|---|---|---|---|
| | Conductivity | Heat Capacity | Expansion |
| Material | (W/mK) | (J/cm³ K) | (ppm/K) |
| Copper | 401 | 3.44 | 16.4 |
| Aluminum | 237 | 2.44 | 24.5 |
| Molybdenum | 138 | 2.57 | 47.5 |
| Gold | 317 | 2.49 | 14.5 |
| Silver | 429 | 2.47 | 18.7 |
| Tungsten Carbide | 95 | 2.95 | 5.7 |
| Silicon | 148 | 1.66 | 2.6 |
| Diamond (IIa) | 2,300 | 1.78 | 1.4 |

In addition, the thermal expansion coefficient of diamond is one of the lowest of all materials. The low thermal expansion of diamond makes joining it with low thermally expanding silicon semiconductor much easier. Hence, the stress at the joining interface can be minimized. The result is a stable bond between diamond and silicon that does not delaminate under the repeated heating cycles.

In recent years diamond heat spreaders have been used to dissipate heat from high power laser diodes, such as that used by laser diodes to boost the light energy in optical fibers. However, large area diamonds are very expensive; hence, diamond has not been commercially used to spread the heat generated by CPUs. In order for diamond to be used as a heat spreader, its surface must be polished so it can make an intimate contact with the semiconductor chip. Moreover, its surface may be metallized (e.g., by Ti/Pt/Au) to allow attachment to a conventional metal heat sink by brazing.

Most current diamond heat spreaders are made of diamond films formed by chemical vapor deposition (CVD) at relatively high temperatures, e.g., greater than 700° C. In addition to being expensive, CVD diamond films can only be grown at very slow rates (e.g., a few micrometers per hour); hence, these films seldom exceed a thickness of 1 mm (typically 0.3-0.5 mm). However, if the heating area of the chip is large (e.g., a CPU), it is preferable to have a thicker (e.g., 3 mm) heat spreader. Further, the differences in thermal expansion between diamond and typical materials such as silicon are acceptable at normal operating temperatures. However, conventional chemical vapor deposition of diamond films occurs at high temperatures, typically in the range of 800° C. As the diamond film and deposition substrate cool to room temperature, the difference in thermal expansion introduces significant residual thermal mismatch stress at the interface between the materials.

In recent years, conventional diamond films have been formed on typical copper heat spreaders with limited success. The thermal expansion mismatch between copper and diamond is even greater than that between diamond and silicon. Thus, conventional diamond deposition processes result in diamond films having extremely high residual thermal mismatch stress at the interface between diamond and copper. Further, conventional diamond deposition requires a diamond nucleation layer when growing on copper due to the well known difficulty of depositing diamond directly on copper surfaces. Again, the nucleation layer materials have differing thermal expansions than diamond and therefore introduce significant residual thermal mismatch stress. The residual thermal stress results in poor reliability and unacceptable delamination of layers during repeated cycling of temperature during normal use.

As such, cost effective systems and devices that are capable of effectively conducting heat away from a heat source, continue to be sought through ongoing research and development efforts.

### SUMMARY OF THE INVENTION

Accordingly, the present invention provides composite heat spreaders that can be used to draw or conduct heat away from a heat source. In one aspect, a diamond composite heat spreader can have a thermally conductive base. The thermally conductive base can be almost any material which would be suitable for use in connection with heat spreaders such as those materials having a thermal conductivity greater than about 200 W/mK. A diamond film can be in thermal contact with the thermally conductive base. In accordance with the present invention, the diamond film and the thermally conductive base can have a residual thermal mismatch stress which is less than about 75% of a residual thermal mismatch stress which would result from forming the diamond film on the thermally conductive base using a high temperature deposition process at 700° C. Thus, the residual thermal mismatch found in heat spreaders of the present invention can be significantly lower than prior art heat spreaders containing diamond materials.

The diamond composite heat spreaders of the present invention can be formed by a method which includes preparing a thermally conductive base. For example, a copper heat spreader or other heat spreader can be cleaned and prepared for vapor deposition of diamond. A diamond film can be formed on the thermally conductive base using a low temperature vapor deposition process performed at a temperature from about 10° C. to less than 700° C. Typically, the low temperature processes useful in the present invention can be performed at temperatures lower than about 450° C. The diamond films further have high thermal diffusivity and thermal conductivity which allow for dramatic improvements in heat transfer away from a heat source without the need for growing a diamond film greater than about 1 μm. Further, in connection with the present invention, diamond films of less than about 500 nm can be inexpensive, effective and reliable.

Optional intermediate layers can be formed on the thermally conductive base which are capable of nucleating diamond under the low temperature vapor deposition process. Carbide forming materials are particularly effective in providing enhanced nucleation.

Conventional vapor deposition processes are typically not suitable for use in the present invention. However, several low temperature vapor deposition processes can be suitable in forming diamond films having reduced thermal mismatch with the underlying substrate. Examples of such processes can include nanodiamond chemical vapor deposition processes, low frequency microwave chemical vapor deposition process, low temperature chemical vapor infiltration, laser ablation, and low temperature argon process. The argon process can be particularly effective in growing the diamond film directly on a thermally conductive copper base. By providing a low temperature deposition of the diamond film, residual thermal mismatch stress can be significantly reduced, while allowing for use of well known and standard copper heat spreaders and associated technologies.

There has thus been outlined, rather broadly, various features of the invention so that the detailed description thereof that follows may be better understood, and so that the present contribution to the art may be better appreciated. Other features of the present invention will become clearer from the following detailed description of the invention, taken with the accompanying claims, or may be learned by the practice of the invention.

### BRIEF DESCRIPTION OF THE DRAWINGS

FIG. 1 is a schematic view of a heat spreader in thermal contact with a heat source and a heat sink in accordance with an embodiment of the present invention.

FIG. 2 is a schematic view of a heat spreader in thermal contact with a heat source and a heat sink via an intermediate layer in accordance with another embodiment of the present invention.

FIG. 3a is a schematic view of a heat spreader in thermal communication with a heat source and a heat sink in accordance with an embodiment of the present invention.

FIG. 3b is a schematic view of a heat spreader in thermal communication with a heat source and a heat sink in accordance with another embodiment of the present invention.

FIG. 3c is a schematic view of a heat spreader in thermal communication with a heat source and a heat sink in accordance with another embodiment of the present invention.

FIG. 4 is a graph of thermal expansion coefficient versus thermal conductivity coefficient for several materials.

It will be understood that the above figures are merely for illustrative purposes in furthering an understanding of the invention. Further, the figures are not drawn to scale, thus dimensions and other aspects may, and generally are, exaggerated to make illustrations thereof clearer. Therefore, departure can be made from the specific dimensions and aspects shown in the figures in order to produce the heat spreaders of the present invention.

### DETAILED DESCRIPTION

Before the present invention is disclosed and described, it is to be understood that this invention is not limited to the particular structures, process steps, or materials disclosed herein, but is extended to equivalents thereof as would be recognized by those ordinarily skilled in the relevant arts. It should also be understood that terminology employed herein is used for the purpose of describing particular embodiments only and is not intended to be limiting.

It must be noted that, as used in this specification and the appended claims, the singular forms “a,” “an” and, “the” include plural referents unless the context clearly dictates otherwise. Thus, for example, reference to “a diamond film” includes one or more of such layers, reference to “an intermediate layer” includes reference to one or more of such layers, and reference to “the base” includes reference to one or more of such materials.

### DEFINITIONS

In describing and claiming the present invention, the following terminology will be used in accordance with the definitions set forth below.

As used herein, “heat spreader” refers to a material which distributes or conducts heat and transfers heat away from a heat source. Heat spreaders are distinct from heat sinks which are used as a reservoir for heat to be held in, until it can be transferred away from the heat sink by another mechanism, whereas a heat spreader may not retain a significant amount of heat, but merely transfers heat away from a heat source.

As used herein, “heat source” refers to a device or object having an amount of thermal energy or heat which is greater than desired. Heat sources can include devices that produce heat as a byproduct of their operation, as well as objects that become heated to a temperature that is higher than desired by a transfer of heat thereto from another heat source.

As used herein, “film” refers to a thin layer of material which is substantially free of non-homogeneous material such as particles of metal, diamond, or the like.

As used herein, “thermal contact” refers to the spatial relationship between materials. Thermal contact can include close proximity between a device or diamond film and a thermally conductive base, which allows for heat transfer from the device toward the thermally conductive base. Thermal contact can also include actual contact between a diamond film and a thermally conductive base, such as in immediately adjacent layers having no intermediate or nucleation enhancing materials.

As used herein, “direct contact” refers to a spatial relationship of two materials where each of the identified materials is in physical contact with the other. Specifically, direct contact of a base and a diamond film excludes intermediate layers, diamond particles, e.g., nucleation enhancing materials, and the like.

As used herein, “diamond film” refers to synthetic diamond material having a crystalline structure. Diamond film can most often be formed using various chemical vapor deposition processes, although other growth or deposition processes may also be suitable. Diamond film can also have a variety of microstructures and nanostructures such as ultrananocrystalline, nanocrystalline, polycrystalline (microcrystalline); and single crystal. For purposes of the present invention, ultrananocrystalline, nanocrystalline, and single crystal are currently preferred.

As used herein, “carbonaceous” refers to any material which is made primarily of carbon atoms. A variety of bonding arrangements or “allotropes” are known for carbon atoms, including planar, distorted tetrahedral, and tetrahedral bonding arrangements. As is known to those of ordinary skill in the art, such bonding arrangements determine the specific resultant material, such as graphite, diamond-like carbon (DLC), or amorphous diamond, and pure diamond. In one aspect, the carbonaceous material may be diamond.

As used herein, “reactive element” and “reactive metal” may be used interchangeably, and refer to an element, especially a metal element that can chemically react with and chemically bond to carbon by forming a carbide bond. Examples of reactive elements may include without limitation, transition metals such as titanium (Ti) and chromium (Cr), including refractory elements, such as zirconium (Zr) and tungsten (W), as well as non-transition metals and other materials, such as aluminum (Al). Further, certain non-metal elements such as silicon (Si) may be included as a reactive element in a brazing alloy.

As used herein “wetting” refers to the process of flowing a molten metal across at least a portion of the surface of a carbonaceous particle. Wetting is often due, at least in part, to the surface tension of the molten metal, and may be facilitated by the use or addition of certain metals to the molten metal. In some aspects, wetting may aid in the formation of chemical bonds between the carbonaceous particle and the molten metal at the interface thereof when a carbide forming metal is utilized.

As used herein, “chemical bond” and “chemical bonding” may be used interchangeably, and refer to a molecular bond that exerts an attractive force between atoms that is sufficiently strong to create a binary solid compound at an interface between the atoms. Chemical bonds involved in the present invention are typically carbides in the case of diamond superabrasive particles, or nitrides or borides in the case of cubic boron nitride.

As used herein, “braze alloy” and “brazing alloy” may be used interchangeably, and refer to an alloy containing a sufficient amount of a reactive element to allow the formation of chemical bonds between the alloy and a superabrasive particle. The alloy may be either a solid or liquid solution of a metal carrier solvent having a reactive element solute therein. Moreover, the term “brazed” may be used to refer to the formation of chemical bonds between a superabrasive particle and a braze alloy.

As used herein, “sintering” refers to the joining of two or more individual particles to form a continuous solid mass. The process of sintering involves the consolidation of particles to at least partially eliminate voids between particles. Sintering may occur in either metal or carbonaceous particles, such as diamond. Sintering of metal particles occurs at various temperatures depending on the composition of the material. Sintering of diamond particles generally requires ultrahigh pressures and the presence of a carbon solvent as a diamond sintering aid, and is discussed in more detail below. Sintering aids are often present to aid in the sintering process and a portion of such may remain in the final product.

As used herein, “substantial” when used in reference to a quantity or amount of a material, or a specific characteristic thereof, refers to an amount that is sufficient to provide an effect that the material or characteristic was intended to provide. The exact degree of deviation allowable may in some cases depend on the specific context. Similarly, “substantially free of” or the like refers to the lack of an identified element or agent in a composition. Particularly, elements that are identified as being “substantially free of” are either completely absent from the composition, or are included only in amounts which are small enough so as to have no measurable effect on the composition.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, particle sizes, volumes, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited.

As an illustration, a numerical range of “about 1 micrometer to about 5 micrometers” should be interpreted to include not only the explicitly recited values of about 1 micrometer to about 5 micrometers, but also include individual values and sub-ranges within the indicated range. Thus, included in this numerical range are individual values such as 2, 3, and 4 and sub-ranges such as from 1-3, from 2-4, and from 3-5, etc. This same principle applies to ranges reciting only one numerical value. Furthermore, such an interpretation should apply regardless of the breadth of the range or the characteristics being described.

Invention

Diamond Composite Heat Spreaders

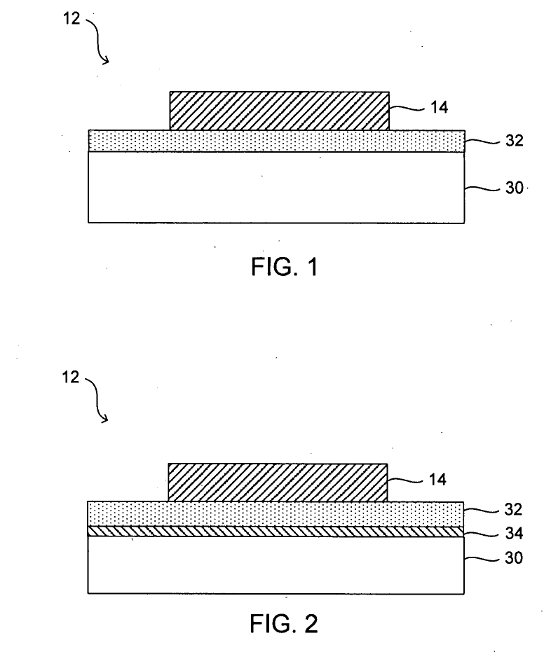

Referring now to FIG. 1, a diamond composite heat spreader 12 is shown having a thermally conductive base 30 in direct contact with a diamond film 32. The thermally conductive base can have a thermal conductivity greater than about 200 W/mK. A wide variety of homogeneous or composite materials can be suitable for use as the thermally conductive base. Generally, the thermally conductive base can comprise a material which can be used to distribute heat away from a heat source 14. Such heat spreading materials preferably have a high thermal conductivity such that heat is transferred away from a heat source. The thermally conductive base can be prepared by any known method such as, but not limited to, sintering, machining, consolidation, infiltration, vapor deposition, purchasing prefabricated substrates, or combinations thereof. As discussed in more detail below, the thermally conductive base is often also cleaned prior to formation of the optional intermediate layer and/or diamond film thereon.

Non-limiting examples of suitable material for use in the thermally conductive base 30 can include copper, aluminum nitride, aluminum, graphite, and alloys or composites thereof. In one embodiment, the thermally conductive base can comprise copper, aluminum, tungsten, molybdenum, aluminum nitride, silicon nitride, or the like. In one currently preferred aspect, the thermally conductive base can consist essentially of copper. In another embodiment, the thermally conductive base can be a diamond composite material such as, 30 but not limited to, diamond-copper, diamond-silicon carbide, diamond-aluminum, and combinations of these types of materials. The thermally conductive base can have any dimensions suitable for use as a heat spreader. Typically, the thermally conductive base can constitute a dominant portion of the final composite heat spreader such that the diamond film and optional intermediate layer contribute less than about 5% to about 10% to the thickness of the composite heat spreader.

In an optional embodiment shown in FIG. 2, the thermally conductive base 30 can be prepared for growth of diamond film 32 by forming an intermediate layer 34 of a carbide forming material which is capable nucleating diamond under the low temperature vapor deposition process. Typically, the nucleation and growth of diamond on standard heat spreading materials such as copper is substantially non-existent. Suitable carbide forming materials for the intermediate layer can include tungsten, silicon, chromium, titanium, molybdenum, and alloys thereof. In one detailed aspect, the intermediate layer can comprise tungsten, silicon, or an alloy thereof. A wide range of specific alloys may be used which attain the desired heat transfer and chemical bonding properties and also allow formation of diamond film thereon. In addition to those materials recited above, the intermediate layer used in the present invention can include a number of other materials. For example, in one aspect of the invention, Cu—Al—Zr (9%) and Cu—Zr (1%) can be used. While Zr is not a particularly good thermal conductor, its presence in the intermediate layer is relatively small by volume, and therefore does not significantly inhibit heat conduction through the heat spreader. As a general guideline, using carbide forming metals can improve bonding of copper with the diamond film, however most carbide formers are thermal insulators. Thus, the degree of carbide bonding with diamond will typically be balanced and counteracted to a degree by thermal resistance.

The intermediate layer 34 is typically a thickness which is sufficient to allow nucleation and growth of diamond thereon without substantially decreasing the overall thermal conductivity of the composite heat spreader 12 across the intermediate layer. Typically, the intermediate layer can have a thickness which is from about 2 nm to about 100 nm, although thicknesses outside this range can also be effectively used.

An additional consideration is the rate at which heat is transferred through a material. Thermal diffusivity is ratio of the thermal conductivity to the volumetric heat capacity (product of density and specific heat) as shown in Equation 1.

$$α = \frac{k}{ρ \cdot {c}_{p}} \qquad Equation 1$$

where k is thermal conductivity, ρ is density, and cₚ is specific heat. Thermal diffusivity is an important measure of the ability of a material to conduct heat relative to its ability to store heat. Thus, materials having a large thermal diffusivity can respond more quickly to changes in thermal gradients than materials having lower thermal diffusivities.

The thermal diffusivity of a heat spreader is important in the design of cooling devices for cooling semiconductor devices such as CPUs, laser diodes, and other high heat devices. Specifically, the average temperature of a device and the associated heat spreader is of less importance than transient peaks in temperature. Thus, although a typical heat spreader can maintain a 4 GHz CPU, for example, at an average temperature which is below a temperature which would cause permanent damage to the device, periodic surges in computation can cause transient spikes in temperature which can result in irreversible damage to the device. A material having a high thermal diffusivity can therefore reduce the likelihood that such temperature spikes will be able to increase the operating temperature of the device beyond a critical value.

Of particular interest are diamond films which have extraordinarily high thermal diffusivities of up to about 10 cm²/sec. A diamond film can be formed which is in thermal contact with the thermally conductive base using a low temperature vapor deposition process performed at a temperature from about 10° C. to less than 700° C. Low temperature vapor deposition processes suitable for use in the present invention are those diamond growth processes which are performed at temperatures below 700° C., and preferably below about 500° C.

One suitable low temperature vapor deposition process is a nanodiamond chemical vapor deposition process. This low temperature process is typically performed at a temperature of about 400° C. This process involves using argon or nitrogen along with methane instead of using hydrogen and methane. For example, 1% methane and 99% argon can be used to deposit nanodiamond film on a substrate at about 400° C. Further, the nanocrystalline domain structure of this diamond film results in properties which are very similar to single crystal diamond. Specifically, the grain boundaries do not significantly interfere with thermal conductivity, unlike larger diamond grains achieved using conventional CVD processes.

In another optional embodiment, the low temperature vapor deposition process can be a low frequency microwave vapor deposition process. The low frequency microwave vapor deposition process can operate at frequencies of less than about 500 MHz, and typically about 150 MHz. Further, this process can be carried out at temperatures from about 150° C. to about 300° C., and typically about 200° C. to produce a high quality diamond film from dissociation of methane.

In addition, low temperature process of chemical vapor infiltration can also be useful in connection with the present invention to allow growth of diamond film into small spaces. During formation of a diamond film on a porous surface chemical vapor infiltration (CVI) typically occurs. Thus, the thermally conductive base can be slightly porous in order to enhance CVI diamond film growth. During CVI, the deposited diamond tends to initially form diamond in the interstitial voids of the diamond particulate region near the surface. Thus, the diamond film is partially integrated into the surface of the particulate diamond region. This helps to decrease the thermal contact resistance along the boundary between the diamond film and the particulate diamond region. Further, this gradual change in composition provides a smoother thermal conductivity gradient than would occur with a distinct boundary.

Yet another optional embodiment includes the use of low temperature argon process as the low temperature vapor deposition process at temperatures less than about 500° C., and typically at about 400° C. In this case, the diamond film can be grown directly on a thermally conductive copper base without the use of a nucleation enhancing layer. A halogenated methane can be used in place of CH₃, and argon, nitrogen, and/or other inert gas can be used instead of hydrogen.

In still another embodiment, the low temperature vapor deposition process can be laser ablation. Laser ablation formation of amorphous diamond film can be achieved at temperatures near ambient. Specifically, laser ablation of graphite under vacuum can be used to produce amorphous diamond suitable for use in the present invention. A laser plasma charge can be directed to a graphite source producing a plasma of C³⁺ and C⁴⁺ which is deposited and quenched on a cold substrate, e.g. the thermally conductive base or intermediate layer. This process can be carried out at room temperature, e.g. about 20° C. However, other temperatures can also be suitable. Although specific characteristics can vary with the substrate and process conditions, in some embodiments the amorphous diamond layer has an sp²/sp³ ratio of about 0.3. The resulting film typically has a nanocrystalline structure 10 nm to about 50 nm in size. Laser ablation can be readily applied substantially homogenously to relatively large surfaces. Further, the thickness of such layers can range from 0.3 μm to about 5 μm although other thicknesses may be desirable for particular heat spreader designs. An additional advantage of laser ablation is an increased ability to deposit a diamond film on a variety of substrates.

In one specific embodiment, a thin layer of carbon black can be applied to a polished copper plate. Laser ablation can then be used to form an amorphous diamond film on the carbon black. In this way, a thin copper substrate can be used with reduced concerns of warping during deposition. This same basic principle can be used to form diamond films on other thin substrates. As a result, thinner substrates can be used and/or fewer costly precautions are necessary in order to prevent warping of substrates common during higher temperature processes.

In yet another alternative embodiment, the low temperature vapor deposition process can be a conformal diamond coating process. Conformal diamond coating processes can provide a number of advantages over conventional diamond film processes. Conformal diamond coating can be performed on a wide variety of substrates, including non-planar substrates. Preferably, the thermally conductive base can be substantially free of diamond fragments. Such fragments can be residual debris from prior polishing or grinding processes used to produce the base. Any diamond fragments or other undesirable debris can be removed by further polishing or other known cleaning steps.

The thermally conductive base can typically be pretreated under diamond growth conditions in the absence of a bias to form a carbon film, although a bias can also be used. The diamond growth conditions can be conditions which are conventional CVD deposition conditions for diamond without or with an applied bias. However, unlike conventional diamond film growth, this pretreatment step generally has a substrate which is substantially free of diamond seed material. As a result, a thin carbon film can be formed which is typically less than about 150 angstroms, e.g. about 4 nm to about 15 nm and most often about 10 nm. The pretreatment step can be performed at almost any growth temperature such as from about 200° C. to about 900° C., although lower temperatures below about 500° C. can be preferred. Without being bound to any particular theory, the thin carbon film appears to form within a short time, e.g., less than one hour, and is a hydrogen terminated amorphous carbon which is conformally adhered to the substrate. Advantageously, the thin carbon film can be formed on a wide variety of substrates, e.g., nickel, glass, copper, ceramics, composites or alloys of these materials, and other similar materials.

The conformally coated substrate can be removed from the reaction chamber and then seeded with a crystalline seed such as micron diamond or nanodiamond. For example, the carbon film can be seeded with diamond using ultrasonic agitation of a dispersion of nanodiamond powder to form a seeded substrate. The dispersion can generally be a dispersion of nanodiamond in methanol although any suitable dispersion can be used. Excess crystalline seeds can be removed by washing. Seeding in this manner can achieve very high nucleation densities, e.g. exceeding 10¹¹/cm². As a result, the micron or nanodiamond can be embedded or partially penetrating the conformal carbon coating.

The seeded substrate can be subjected to diamond growth conditions to form the diamond film as a conformal diamond film. The diamond growth conditions can be those conditions which are commonly used in traditional CVD diamond growth. However, unlike conventional diamond film growth, the diamond film produced using the above pretreatment steps results in a conformal diamond film. Thus, “pretreatment” indicates prior to the presence of crystalline seed material. Further, the diamond film typically begins growth substantially over the entire substrate with substantially no incubation time. In addition, a continuous film, e.g. substantially no grain boundaries, can develop within about 80 nm of growth. The conformal diamond film growth closely follows the contours of the substrate surface. Without being bound to a particular theory, during diamond growth of the above seeded conformal carbon coating, diamond growth appears to grow laterally rather than conventional vertical and columnar growth. The carbon coating is substantially consumed in the formation of diamond and as the diamond film thickness exceed about 1 micron the diamond film growth tends to follow conventional diamond film. However, the conformal diamond film results in a smooth starting or growth face against the substrate having reduced deformities and fewer gaps.

Although suitable conditions can vary, process temperatures can be held below about 500° C. with good results. For example, temperatures from about 250° C. to about 500° C. can be useful and from about 300° C. to about 450° C. can generally be preferred. Growth conditions do not need to be the same as those used during the pretreatment step and can vary substantially therefrom. For example, conventional CVD diamond growth conditions can be used in the pretreatment step to form the thin carbon film, while plasma or laser ablation conditions can be used during the growth step. Conformal diamond films can typically have a thermal conductivity from about 800 W/mK to about 2200 W/mK, although even higher thermal conductivities may be possible. For example, a conformal thin film of about 3.5 μm was measured having a thermal conductivity of about 1300 W/mK and a film of about 250 μm had a thermal conductivity of about 2180 W/mK. Further, conformal diamond films appear to have optical properties which are substantially similar to those of pure diamond. Conformal diamond films of almost any thickness can be used. However, typically thicknesses from about 0.2 μm to about 1 mm, and preferably from about 0.5 μm to about 50 μm, are sufficient to provide exceptional heat spreading properties to the diamond composite heat spreaders of the present invention. For example, for typical configurations and applications, a conformal diamond film thickness of about 10 μm can provide adequate results.

In another alternative embodiment, the diamond film can be formed on a first thermally conductive base. Although other types of diamond films can be used, conformal diamond films can be deposited on a wide variety of substrates such as thermally conductive silicon, graphite foil, or other suitable materials. A layer of high thermal conductivity material can then be deposited on the conformal diamond coating opposite the first thermally conductive base. Typically, the high thermal conductivity material can be copper; however, any material having a thermal conductivity of at least about 300 W/mK can be useful, depending on the specific requirements. The layer of high thermal conductivity material can be deposited using any known method, e.g., physical deposition, vapor deposition, chemical, or electrodeposition. Currently, preferred processes include electrodeposition and most preferred is electroless deposition of copper.

The deposited high thermal conductivity material can then act as a joining layer for joining to a heat spreader to form a diamond composite heat spreader. Typically, heat spreaders comprise or consist essentially of copper; therefore, a joining layer comprising copper is often preferred. The high thermal conductivity material can be joined using any suitable method such as, but not limited to, brazing, welding, friction welding, etc. Most often the heat spreader, high thermal conductivity material, and any optional brazing or joining materials can include substantially similar compositions in order to improve heat flow across boundaries and provide for a more homogeneous final product.

When a conformal diamond film is formed on silicon as the thermally conductive base, the silicon can be left in place to serve as a layer for building a silicon device or can be optionally removed. Alternatively, the thermally conductive base can be a silicon device such that a silicon on diamond (SOD) device is formed in situ having a diamond composite heat spreader built in. For example, a processed uncut wafer (Si, GaN, etc.) having various semiconductor devices (IC, LED, etc.) formed thereon using conventional technologies can be subjected to the processes described herein as the thermally conductive base. Due to the low temperatures involved in the present invention, the deposition conditions do not damage the semiconductor device. The wafer can then be further coated with a thicker layer of copper, diced and/or packaged in a conventional manner to form an integrated heat spreader-semiconductor component. Similarly, in embodiments which coat conformal diamond on graphite foil, the graphite foil can serve as a thermal interface material (TIM) layer. Other low temperature processes can also be used to form various diamond films and can be implemented in practice of the present invention.

Further, in accordance with the principles of the present invention the diamond film is formed such that the diamond film and the thermally conductive base have a residual thermal mismatch stress which is less than about 75% of a residual thermal mismatch stress which would result from forming the diamond film on the thermally conductive base using a high temperature deposition process at 700° C. Depending on the deposition temperature, the residual thermal mismatch stress can be reduced even further, such as less than about 60%, and preferably less than about 30% of the stress resulting from a 700° C. deposition process.

Without being bound to following illustration, the residual thermal mismatch stress can be estimated using Equation 2.

$$σ = \frac{E}{1 - v} ( {α}_{f} - {α}_{s} ) Δ T \qquad Equation 2$$

where σ is the residual thermal mismatch stress, E is Young's modulus, ν is Poisson ratio, α_{f} is the film linear expansion coefficient, αₛ is the substrate linear expansion coefficient, and ΔT is the temperature difference between the deposition temperature and the operating temperature of the device at the interface.

TABLE 2
Thermal and Mechanical Properties of Several Materials

| Material | α (1/K) × 10⁶ | ν | E (GPa) |
|---|---|---|---|
| CVDD | 1.0 | 0.2 | 1,200 |
| Cu | 16.6 | 0.35 | 110 |
| Si | 3.0 | 0.17 | 150 |
| W | 4.5 | 0.28 | 407 |
| Ti | 4.9 | 0.36 | 116 |
| SiC | 4.7 | 0.19 | 450 |

The above residual thermal mismatch stress (σ) normal to the plane of the film does not include the additional mismatch stress resulting from peeling of adjacent layers via stresses which are non-normal to the plane near the edges of film. However, this estimation is a very good approximation for purposes of designing composite heat spreaders in connection with the present invention. Using the above information, a conventional CVD diamond film deposited on copper (without taking into account the nucleation layer) at 700° C. would have a residual thermal mismatch stress of about 1.7 GPa. Conversely, using low temperature vapor deposition processes of diamond film on copper result in residual mismatch stresses of 0.92 GPa and 0.40 GPa at 400° C. and 200° C., respectively. This represents a decrease of over about 46% and 76%, respectively, over conventional high temperature processes. In accordance with the present invention, a residual thermal mismatch stress of less than about 1.5 GPa can be useful, and is preferably less than about 1 GPa, inclusive of an optional intermediate layer.

The diamond films of the present invention can vary somewhat in terms of thermal diffusivity, thermal conductivity, and crystalline structure. However, as a general guideline, the diamond film can have a thermal diffusivity from about 2 cm²/sec to about 13 cm²/sec and a thermal conductivity from about 800 W/mK to about 2500 W/mK, and preferably from about 1000 W/mK to about 2400 W/mK. As a point of reference, copper has a thermal diffusivity of about 1.17 cm²/sec and a thermal conductivity of about 400 W/mK. In one preferred embodiment, the diamond film can have a thermal diffusivity from about 6 cm²/sec to about 10 cm²/sec.

The diamond film of the present invention can have a thickness which is sufficient to enhance removal of heat from a heat source. In one aspect, the diamond film can have a thickness from about 20 nm to about 1 μm, and preferably from about 100 nm to about 0.8 μm, although other thicknesses can also be used.

Incorporation of Diamond Composite Heat Spreaders for Heat Removal

Heat spreaders made in accordance with the present invention may take a variety of configurations based on the intended use. The carbonaceous material made as described above may be polished and shaped based on the particular requirements of the heat source to which it will be applied. The diamond composite heat spreaders herein can be formed to almost any size relatively quickly by designing a thermally conductive base having the desired dimensions. Most often for electronic applications the heat spreader will be between about 0.1 mm and about 1 mm thick. The heat spreader may be formed into a circular or elliptical disk or a quadrilateral such as a square, rectangular or other shaped wafer. The heat source may be any electrical or other component which produces heat.

Once the heat spreader is formed, appropriate placement is based on design and heat transfer principles. The heat spreader may be in direct intimate contact with the component, and may even be formed to encompass or otherwise be contoured to provide direct contact with the heat source over a wide surface area. Alternatively, the heat spreader may be removed from the heat source by a heat conduit or other heat transfer device.

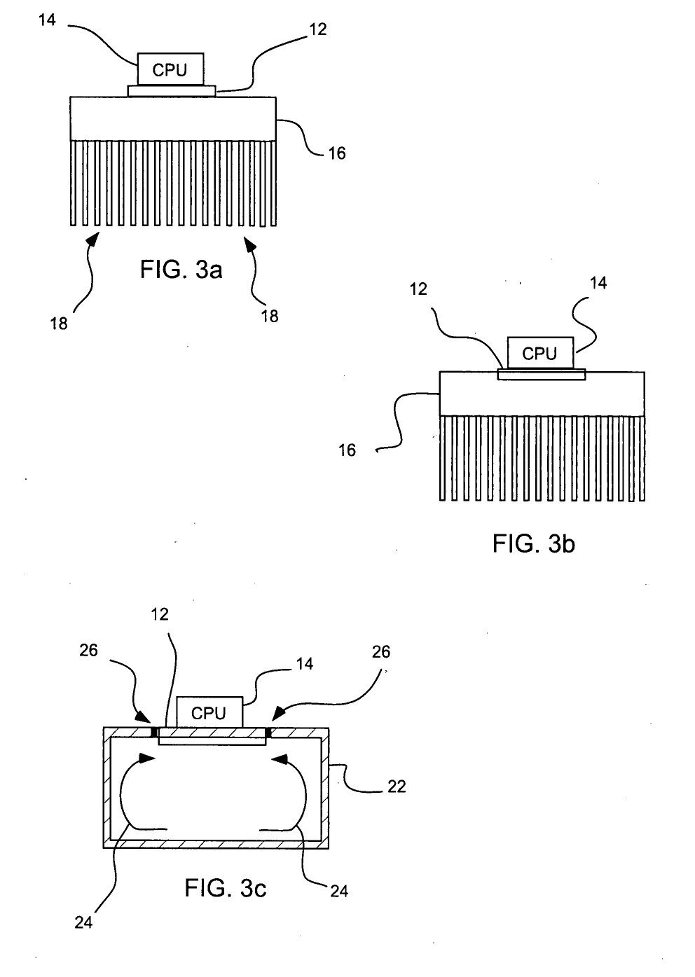

In addition to the heat spreader disclosed herein, the present invention encompasses a cooling unit for transferring heat away from a heat source. As shown in FIG. 3a, a heat spreader 12, formed in accordance with the principles discussed herein, can be disposed in thermal communication with both a heat source, such as a CPU 14, and a heat sink 16. The heat spreader transfers heat created by the CPU to the heat sink. The heat sink can be a number of heat sinks known to those of ordinary skill in the art including both the materials and configurations thereof. For example, aluminum and copper are well known for use as heat sinks, and as shown in FIG. 3a, can have a configuration that includes cooling fins 18. As heat is quickly and efficiently transferred from the CPU through the heat spreader, the heat sink absorbs the heat, and the cooling fins help dissipate the heat into the surrounding environment. A number of contact configurations between the heat sink, heat source, and heat spreader can be utilized depending on the specific results to be achieved. For example, the components may be disposed adjacent each other and can also be bonded or otherwise coupled to each other. In one aspect of the invention, the heat spreader can be brazed to the heat sink.

While the heat sink 18 is shown in the figures as a sink including cooling fins, it is to be understood that the present invention can be utilized with any heat sink known to those in the art. Examples of known heat sinks are discussed in U.S. Pat. No. 6,538,892, which is herein incorporated by reference. In one aspect of the invention, the heat sink comprises a heat pipe having an internal working fluid. Examples of heat pipe heat sinks are discussed in U.S. Pat. No. 6,517,221, which is herein incorporated by reference.

As shown in FIG. 3b, in one aspect of the invention, the heat spreader 12 can be at least partially embedded in the heat sink and/or the heat source. In this manner, not only is heat transferred from a bottom of the heat spreader to the heat sink, but heat is also at least partially transferred from sides of the heat spreader into the heat sink. After being embedded in the heat sink, the heat spreader can be bonded or brazed to the heat sink. In one aspect, the heat spreader can be held in the heat sink by a compression fit. In this manner, no bonding or brazing material exists between the heat spreader and the heat sink, which might act as a barrier to efficient heat transfer from the spreader to the sink.

While the heat spreader can be held in the heat sink by a variety of mechanisms known to those skilled in the art, in one aspect the heat spreader is held in the heat sink by a thermally induced compression fit. In this embodiment, the heat sink can be heated to an elevated temperature to expand an opening formed in the heat sink. The heat spreader can then be fitted into the expanded opening and the heat sink can be allowed to cool. Upon cooling, the heat sink, which has a relatively high coefficient of thermal expansion, will contract around the heat spreader and create a thermally induced compression fit that holds the heat spreader embedded within the heat sink without requiring any intervening bonding material. A mechanical friction fit can also be utilized to hold the heat spreader in the heat sink.

As shown in FIG. 3c, in one aspect of the invention, the heat sink can comprise a heat pipe 22 which can have an internal working fluid (not shown). The internal working fluid can be any known to those in the art, and in one aspect is water or water vapor. The heat pipe can be substantially sealed to maintain the working fluid within the heat pipe. The heat spreader can be disposed adjacent the heat pipe and in one aspect is brazed to the heat pipe. In the embodiment shown in FIG. 3c, the heat spreader protrudes through a wall of the heat pipe so that a bottom of the heat spreader is in direct contact with the working fluid. The heat spreader can be brazed within the heat pipe, as shown at 26, to assist in maintaining the substantially sealed condition of the heat pipe.

As the heat spreader is in direct contact with the working fluid, the working fluid can more efficiently transfer heat from the heat spreader. In the embodiment shown in FIG. 3c, the working fluid, in this case water (not shown), contacts the heat spreader and becomes vaporized as it absorbs heat from the heat spreader. The water vapor can then condense in liquid form on the bottom of the heat pipe, after which, due to capillary forces, the liquid will migrate 24 back up the walls of the heat pipe to the heat spreader, where it will again vaporize and repeat the cycle. As the walls of the heat pipe can be made of a material with a high coefficient of thermal conductivity, heat is dissipated from the walls of the heat pipe into the surrounding atmosphere. In another aspect, a method of cooling a heat source is provided and includes the steps of providing a heat spreader as recited in the various aspects described above, and placing the heat spreader in thermal communication with both the heat source and a heat sink.

One advantage of using a diamond film in connection with the present invention is that diamond films have extremely good thermal conductivities, e.g., typically approaching that of pure diamond (2400 W/mK), but are expensive and time consuming to produce an effective heat spreader. However, when used in conjunction with particulate diamond regions as described herein, the thickness of the diamond film can be reduced. For example, in some embodiments, the diamond film can have a thickness of from about 0.1 mm to about 1 mm, such as from about 0.3 mm to about 0.7 mm, and preferably about 0.5 mm. In this way, the high thermal conductivity of diamond film can quickly remove heat from a heat source while the adjacent particulate diamond region then transfers the heat further away from the heat source at a somewhat lower, but still relatively high rate. This is particularly beneficial when cooling many electronic components, e.g., CPUs, where high temperatures are only temporary and fluctuate over time. Thus, a thin diamond film layer can be provided which is sufficient to transfer heat toward the particulate diamond region without sacrificing removal of heat from the heat source. In embodiments including a diamond film heat influx region can have a thermal conductivity up to 2500 W/mK and the thermally conductive base heat exit region can have a thermal conductivity from about 200 w/mK to about 2000 W/mK, and typically from about 200 W/mK to about 1000 W/mK.

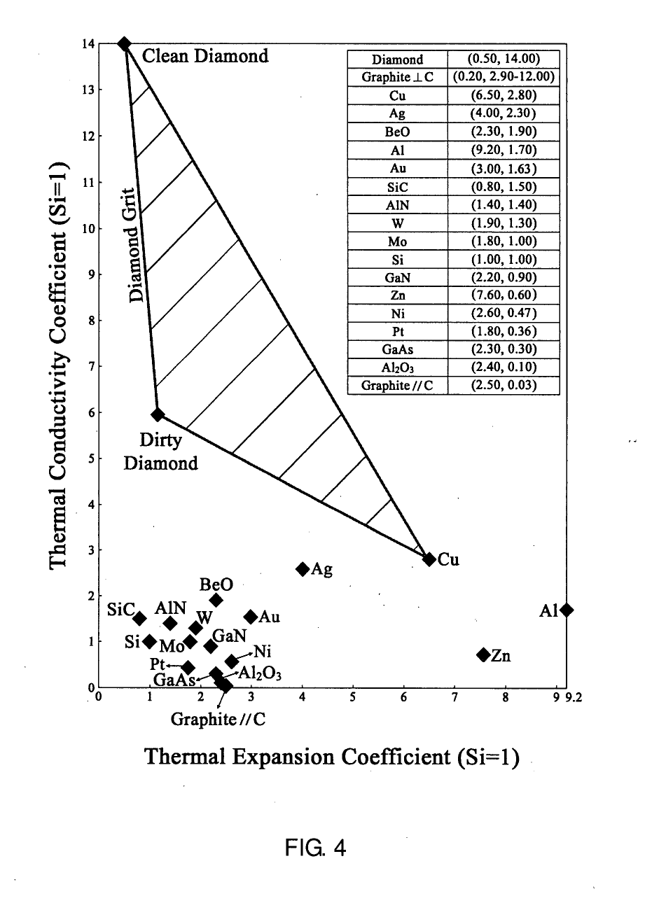

In addition to the above considerations, thermal expansion can affect the choice of potential materials for use in the present invention. For example, FIG. 4 illustrates thermal expansion coefficients versus thermal conductivity coefficients for several potentially useful materials. The enclosed triangular region represents the approximate region over which most of the diamond composite and diamond-containing materials of the present invention fall. Preferably, any materials such as interstitial material, braze, or any adjacent layers can have a thermal expansion coefficient which is substantially similar to the diamond materials. Specifically, a large difference in thermal expansion can cause unnecessary fatigue and stress within the diamond materials during use. With respect to nomenclature, “graphite⊥C” refers to the property of graphene planes perpendicular to the “c” crystallographic axis, while “graphite//C” refers to the property parallel to the “c” crystallographic plane. This highlights the anisotropic nature of graphite. Also, the values of thermal conductivity and thermal expansion are normalized with respect to silicon for convenience in matching the materials of the present invention for use with silicon devices.

Of course, it is to be understood that the above-described arrangements are only illustrative of the application of the principles of the present invention. Numerous modifications and alternative arrangements may be devised by those skilled in the art without departing from the spirit and scope of the present invention and the appended claims are intended to cover such modifications and arrangements. Thus, while the present invention has been described above with particularity and detail in connection with what is presently deemed to be the most practical and preferred embodiments of the invention, it will be apparent to those of ordinary skill in the art that numerous modifications, including, but not limited to, variations in size, materials, shape, form, function and manner of operation, assembly and use may be made without departing from the principles and concepts set forth herein.

What is claimed is:

1. A diamond composite heat spreader, comprising:
a) a thermally conductive base having a thermal conductivity greater than about 200 W/mK; and
b) a diamond film in direct contact with the thermally conductive base and being substantially free of an intermediate layer.

2. The method of claim 1, wherein the thermally conductive base comprises copper, silicon, or graphite foil.

3. The heat spreader of claim 1, wherein the thermally conductive base consists essentially of copper.

4. The heat spreader of claim 1, wherein the diamond film and the thermally conductive base have a residual thermal mismatch stress which is less than about 75% of a residual thermal mismatch stress which would result from forming the diamond film on the thermally conductive base using a high temperature deposition process at 700° C.

5. The heat spreader of claim 4, wherein the residual thermal mismatch stress is less than about 1.5 GPa.

6. The heat spreader of claim 4, wherein the residual thermal mismatch stress is less than about 65% of a residual thermal mismatch stress which would result from forming the diamond film on the thermally conductive base using a high temperature deposition process at 700° C.

7. The heat spreader of claim 6, wherein the residual thermal mismatch stress is less than about 30% of a residual thermal mismatch stress which would result from forming the diamond film on the thermally conductive base using a high temperature deposition process at 700° C.

8. The heat spreader of claim 1, wherein the diamond film has a thermal diffusivity from about 6 cm²/sec to about 10 cm²/sec.

9. The heat spreader of claim 1, wherein the diamond film has an sp²/sp³ ratio of about 0.3.

10. The heat spreader of claim 1, wherein the diamond film has a thickness from about 20 nm to about 1 μm.

11. The heat spreader of claim 1, wherein the thermally conductive base comprises a member selected from the group consisting of copper, aluminum nitride, aluminum, graphite, and alloys or composites thereof.

12. The heat spreader of claim 1, wherein the thermally conductive base comprises silicon.

13. The heat spreader of claim 12, wherein the thermally conductive base includes semiconductor devices thereon.

14. The heat spreader of claim 1, wherein the thermally conductive base comprises a diamond composite material.

15. The heat spreader of claim 14, wherein the diamond composite material is a diamond-copper composite, diamond-silicon carbide composite, diamond-aluminum composite, or combination thereof.

16. The heat spreader of claim 1, wherein the thermally conductive base has a non-planar surface with which the diamond film is in direct contact.

17. The heat spreader of claim 1, wherein the diamond film is nanocrystalline diamond or a conformal diamond film.

18. The heat spreader of claim 1, wherein the diamond film has a thermal conductivity from about 800 W/mK to about 2500 W/mK.

19. A diamond composite heat spreader, comprising:
a) a thermally conductive base having a thermal conductivity greater than about 200 W/mK; and
b) a diamond film in thermal contact with the thermally conductive base such that the diamond film and the thermally conductive base have a residual thermal mismatch stress which is less than about 75% of a residual thermal mismatch stress which would result from forming the diamond film on the thermally conductive base using a high temperature deposition process at 700° C. and said thermally conductive base comprising copper, silicon or a diamond composite material.

20. The heat spreader of claim 19, wherein the diamond film is nanocrystalline diamond or a conformal diamond film.
